(19) United States
(12) Patent Application Publication
(10) Pub. No.: US 2025/0279255 A1
(43) Pub. Date: Sep. 4, 2025

(54) PROTECTION THROUGH A POWER TRANSFORMER USING COMPENSATED VOLTAGES AND CURRENTS

(71) Applicant: Schweitzer Engineering Laboratories, Inc., Pullman, WA (US)

(72) Inventors: Dale S. Finney, Little Bras D'or (CA); Bogdan Z. Kasztenny, Markham (CA)

(73) Assignee: Schweitzer Engineering Laboratories, Inc., Pullman, WA (US)

(21) Appl. No.: 19/050,973

(22) Filed: Feb. 11, 2025

Related U.S. Application Data
(60) Provisional application No. 63/559,276, filed on Feb. 29, 2024.

(51) Int. Cl. H01H 83/18; G01R 31/62; H01H 47/00

(52) U.S. Cl. CPC H01H 83/18; G01R 31/62; H01H 47/002

(57) ABSTRACT

A distance protection element for fault coverage through a transformer that introduces a break in the zero-sequence equivalent network is disclosed herein. Voltage and current signals from a delta (low) side of the transformer are obtained and compensated using wye (high) side neutral current and nominal values. The compensated voltage and current signals are used in a distance protection element to detect faults on the wye (high) side of the transformer. The distance protection element may be implemented in a generator protection device as backup distance protection.

### RELATED APPLICATIONS

This application claims priority from and benefit of U.S. Provisional Application Ser. No. 63/559,276 filed on 29 Feb. 2024 entitled “Correcting Voltages and Currents to Enable Comprehensive Protection Through a Power Transformer” which is hereby incorporated by reference in its entirety for all purposes.

### TECHNICAL FIELD

This disclosure relates to distance protection through a transformer in electric power delivery systems. More specifically, this disclosure relates to distance protection through a transformer that introduces a break in the zero-sequence equivalent network.

### BRIEF DESCRIPTION OF THE DRAWINGS

Non-limiting and non-exhaustive embodiments of the disclosure are described, including various embodiments of the disclosure with reference to the figures, in which:

FIG. 1 illustrates a simplified one-line diagram of an electric power delivery system comprising an Intelligent Electronic Device (IED) implementing distance protection in accordance with several embodiments herein.

FIG. 2 illustrates a simplified connection diagram of a delta-wye-connected transformer in accordance with several embodiments herein.

FIG. 3 illustrates a flow chart for determining compensated voltages and currents in accordance with several embodiments herein.

FIG. 4 illustrates mho characteristics for a distance protection element in accordance with several embodiments herein.

FIG. 5 illustrates quadrilateral characteristics for a distance protection element in accordance with several embodiments herein.

In the following description, numerous specific details are provided for a thorough understanding of the various embodiments disclosed herein. However, those skilled in the art will recognize that the systems and methods disclosed herein can be practiced without one or more of the specific details, or with other methods, components, materials, etc. In addition, in some cases, well-known structures, materials, or operations may not be shown or described in detail in order to avoid obscuring aspects of the disclosure. Furthermore, the described features, structures, or characteristics may be combined in any suitable manner in one or more alternative embodiments.

### DETAILED DESCRIPTION

Electric power delivery systems generally comprise equipment and devices for the generation, transformation, transmission, distribution, and consumption of electric power. Such systems are typically monitored and protected by IEDs that obtain electrical measurements such as voltage and current from the power system and use those measurements to determine a condition of the power system. IEDs may perform a protective action (such as signaling a circuit breaker to trip) under certain determined conditions. For example, an IED may include a distance protection element that uses signals obtained from the electric power delivery system to determine a fault condition and whether that fault condition is detected to be within a zone of protection of the particular protection element of the IED. If the fault is detected to be within that zone of protection, the IED may signal a circuit breaker to trip.

Generator protective relays may be IEDs that are configured to determine conditions of a generator, and take a protective action under certain detected conditions. Such IEDs may further be used to provide backup protection to protect the generator and the power system in the event of an uncleared fault on the power system. The zone of coverage of the backup element may begin at the generator terminals and extend into the power system through a step-up transformer. Typically, distance elements are used to provide backup protection for phase faults, and zero-sequence overcurrent elements are used to provide backup for ground faults. A generator protective IED may obtain power system signals such as voltages and currents from the generator terminals. In certain implementations, these may be sufficient for backup distance protection to be provided by the generator protective IED. However, as discussed below, these signals may be inadequate to provide distance protection through certain power system equipment.

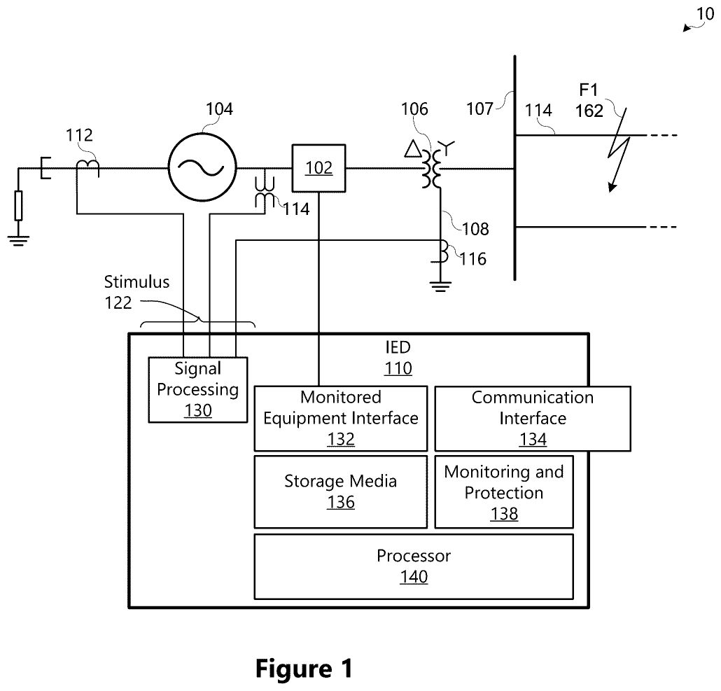

Generators often connect to the electric power system through a generator step-up transformer (GSU). The GSU transformer is typically delta-connected on the generator (low voltage) side as of the GSU is shown in FIG. 1. The delta connection isolates the generator equivalent zero-sequence network from the transmission system zero-sequence network. This allows the generator to be grounded through a high impedance, limiting damage for ground faults and allowing the use of generator ground fault protection schemes that cover the entire stator winding. However, the open circuit in the zero-sequence network does not allow the generator backup distance element to accurately detect system ground faults using the generator terminal voltages and currents. Thus, the generator may be left without the backup ground distance protection extending into the electric power delivery system. The embodiments discussed herein provide ground distance protection through a transformer using the available signals even when the transformer introduces a break in the zero-sequence network (such as a delta-wye power transformer). Although several embodiments are drawn specifically toward a delta-wye GSU and use voltages and currents from generator terminals, these embodiments may be more generally applied in any distance protection element in the presence of a transformer-induced break in the zero-sequence network.

The electric power delivery systems referenced herein may include a high-voltage transmission network on the high side of the GSU. A generator protective IED or a system of IEDs may include zones of coverage for distance protection that are intended to extend past the GSU into the high-voltage transmission network. The IED (or a system of IEDs) may operate multiple distance protection elements (“zones”), each with a configured reach, and each of which may be time coordinated. System protection schemes may be time coordinated with, for example, generator backup distance protection such that the system protection schemes are given time to operate first. Many factors impact the application of backup protection including protection redundancy, use of breaker failure protection, and bus configuration.

FIG. 1 illustrates a simplified one-line diagram of a portion of an electric power delivery system 10 comprising an IED 110 implementing distance protection in accordance with several embodiments herein. The illustrated portion of the electric power delivery system illustrated includes a generator 104, circuit breaker 102, delta-wye-connected step-up transformer 106, bus 107 between the transformer 106 and the transmission lines (e.g. 114) originating at the bus 107. A current transformer (CT) 112 on the generator terminals may provide secondary signals related to the current in each phase of the multi-phase generator. Potential transformer (PT) 114 may provide signals related to the voltages of each phase on the generator side of the transformer 106. The transformer 106 may step up the voltage of the electric power from the generator from a generator (low-side) level to a transmission (high-side) level. Transformer 106 may introduce a break in the equivalent zero-sequence network. As illustrated, the transformer 106 is a delta-wye-connected transformer with the generator on the delta side and the transmission system on the wye side. Circuit breaker 102 may be closed to connect the generator 104 to the transformer 106, and opened to disconnect the generator 104 from the transformer (and from downstream power system equipment) when certain conditions are detected. Optionally, the breaker can be installed on the high-voltage side of the transformer instead of the low-voltage side. The system may include various other lines, branches, transformers, buses, loads, and the like, but is illustrated in simplified form for ease of discussion herein.

A CT 116 may be placed in electrical communication with a neutral 108 of the wye-side of the transformer 106 and may provide to the IED 110 signals related to the neutral-point current I_{HN}. Generator protective IEDs and transformer protective IEDs may implement inverse-time overcurrent protection using neutral-point currents. Such inverse-time overcurrent elements may be used form backup protection for an uncleared system fault involving ground. As this element requires only one signal, it is an inexpensive backup protection for generator and transformer IEDs. Thus, the neutral-point current is a signal available in certain IEDs such as generator protection relays and transformer relays along with the delta-side current and voltage signals.

The IED 110 provides electric power system protection such as generator protection, distance protection, overcurrent protection, backup protections and the like. The illustrated IED 110 includes a processor 140 for executing computer instructions, which may comprise one or more general purpose processors, special purposes processors, application-specific integrated circuits, programmable logic elements (e.g., FPGAs), or the like. The IED 110 may further comprise non-transitory machine-readable storage media 136, which may include one or more disks, solid-state storage (e.g., Flash memory), optical media, or the like for storing computer instructions, measurements, settings and the like. In various embodiments the storage media 136 may be packaged with the processor 140, separate from the processor 140, or there may be multiple physical storage media 136 including media packaged with the processor 140 and media 136 separate from the processor 140.

The IED 110 may be communicatively coupled to other IEDs and/or supervisory systems either directly or using one or more communication networks via one or more communication interfaces 134. In some embodiments, the IED 110 may include human-machine interface (HMI) components (not shown), such as a display, input devices, and so on.

The IED 110 may include a plurality of monitoring and protection elements, described as a monitoring and protection module 138 that may be embodied as instructions stored on computer-readable media (such as storage media 136). The instructions, when executed on the processor 140, cause the IED to detect a fault and may also cause the IED to execute a protective action in response to the detected fault (e.g. signaling a circuit breaker to open the appropriate phases), display fault information, send messages including the fault information, and the like. Methods disclosed herein may generally follow the instructions stored on media for system protection.

The monitoring and protection module 138 may include protection elements such as, for example, stator current unbalance, various overcurrent elements, phase distance elements, time overcurrent elements, and the like. The storage media 136 may include protective action instructions to cause the IED 110 to signal a circuit breaker 102 to open via the monitored equipment interface 132 upon detection of a fault condition.

The IED 110 may obtain electrical signals (the stimulus 122) from the power system 10 through instrument transformers (CTs, PTs, or the like). The stimulus 122 may be received directly via the measurement devices described above and/or indirectly via the communication interface 134 (e.g., from another IED or other monitoring device (not shown) such as a merging unit of the electrical power system 10). The stimulus 122 may include, but is not limited to: current measurements, voltage measurements, equipment status (breaker open/closed) and the like.

The IED includes a signal processing module 130 to receive the electric power system signals and process the signals for monitoring and protection such as distance protection. Line currents and voltages are sampled at a rate suitable for protection, such as in the order of kHz to MHz. An analog-to-digital converter (ADC) may be included to create digital representations of the incoming line current and voltage measurements. The output of the ADC may be made available to the processor 140 and used in various embodiments herein. As illustrated, the signal processing 130 receives analog signals from instrument transformers in electrical communication with equipment of an electric power delivery system, and processes those signal for use in the processor 140.

Although not separately illustrated, in various embodiments the IED 110 may receive digitized analog signals from external units such as merging units that receive analog power system signals and transmit the digitized analog signals to the IED. These digitized analog signals may be processed by the signal processing module 130 for use by the processor 140.

A monitored equipment interface 132 may be in electrical communication with monitored equipment such as circuit breaker 102. Circuit breaker 102 is configured to selectively trip (open) upon receipt of a trip command from the IED 110. The monitored equipment interface 132 may include hardware for providing a signal to the circuit breaker 102 to open and/or close. In its backup capacity, the IED 110 may be configured to detect a fault 162 and determine whether the fault is within the zone of protection. If such a fault within the zone of protection is determined, the monitoring and protection module 138 is configured to determine a protective action and effect the protective action on the power system by, for example, signaling the monitored equipment interface 132 to provide an open signal to the appropriate circuit breaker 102. The determined protective action may include a time delay for signaling the breaker to open based on the zone in which the fault is determined to have occurred. Upon detection of the fault and determination that the fault is within the zone of protection, the IED 110 may signal other devices (using, for example, the network, or signaling another device directly by using inputs and outputs) regarding the fault, which other devices may signal a breaker to open, thus effecting the protective action on the electric power delivery system.

IED 110 is configured to detect faults on the generator and a portion of the electric power delivery system. IED 110 includes distance protection elements to determine a fault, determine if the fault is internal to the protected zone, and send a trip signal to circuit breaker 102. The distance element includes several components, including directional determination, faulted loop determination, and distance determination. The distance element in accordance with several embodiments herein is configured to provide backup protection to a zone that extends past the transformer 106 even if the transformer introduces a break in the zero-sequence network.

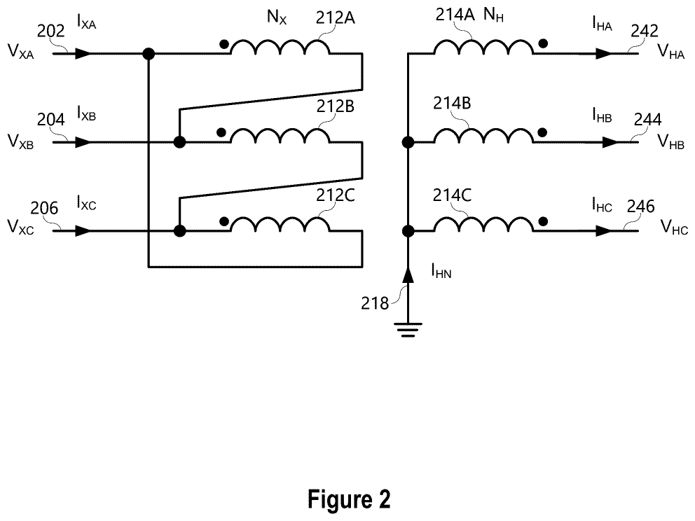

FIG. 2 illustrates a simplified connection diagram 200 of a transformer in accordance with several embodiments. The diagram illustrates connections of a GSU transformer configured with a delta winding 212A-C on the X-side (low, generator, or delta side) and wye windings 214A-C on the H-side (high, transmission, or wye side). This delta-wye configuration introduces a break in the zero-sequence equivalent network between the low side and the high side. Although a GSU transformer is illustrated, the embodiments herein may be used to provide distance protection through any transformer that introduces a break in the zero-sequence network using low-side voltages and currents, and high-side neutral current.

The delta-side transformer A-phase 212A, B-phase 212B and C-phase windings 212C are in delta configuration, and are in electrical connection with the A-phase 202, B-phase 204 and C-phase 206 inputs, respectively. Wye-side A-phase 214A, B-phase 214B and C-phase windings 214C are in wye configuration, and in electrical communication with A-phase 242, B-phase 244, and C-phase outputs 246. Further, the wye-side includes a neutral connection to ground 218. N_{X} is the number of delta-side windings, and NH is the number of wye-side windings. The figure also shows winding polarity by using dot symbols. As is shown in FIG. 1, signals related to phase voltages and currents (V_{XA}, V_{XB}, V_{XC}, I_{XA}, I_{XB}, and I_{XC}) from the delta side of the transformer and signals related to current on the neutral I_{HN} are available to the IED, but currents and voltages from the wye side of the transformer are not available to the IED.

A generator protective relay (such as IED 110) measures stator voltages and currents, i.e., voltages and currents at the delta side of the GSU transformer. Generator protective relays often also measure the current in the neutral connection of the GSU transformer's wye-side. Because of the break in the zero-sequence equivalent network, the delta-side currents and voltages themselves are inadequate to use in distance protection elements for protection on the wye side of the transformer. That is, traditional distance protection through a transformer would require signals from the wye (high-voltage) side of the transformer when there is a break in the zero-sequence networks. Without the embodiments herein, the generator protective relay would not provide adequate distance protection to the wye side of the transformer because the wye-side voltages and currents are not available to the relay. The embodiments herein may be used to calculate compensated voltages and currents for the wye-side of the transformer using the available signals (delta-side currents and voltages and the wye-side neutral current) to provide distance protection coherent with the wye-side of the transformer. Because other primary protection devices may be used for distance protection on the wye-side of the transformer, the generator protection relay can be used to provide backup distance protection to the primary distance protection. The backup protection may use a time delay to allow the primary protection to react first to detected faults.

The compensated voltages and currents may be calculated using Equations 1-4:

$$\begin{matrix}{V}_{A} = {V}_{XA} - {V}_{XB} + {I}_{COMP} \cdot {Z}_{COMP} \\ {V}_{B} = {V}_{XB} - {V}_{XC} + {I}_{COMP} \cdot {Z}_{COMP} \\ {V}_{C} = {V}_{XC} - {V}_{XA} + {I}_{COMP} \cdot {Z}_{COMP}\end{matrix} \qquad Eq . 1$$

$$\begin{matrix}{I}_{A} = {I}_{XA} - {I}_{XB} = {I}_{COMP} \\ {I}_{B} = {I}_{XB} - {I}_{XC} = {I}_{COMP} \\ {I}_{C} = {I}_{XC} - {I}_{XA} = {I}_{COMP}\end{matrix} \qquad Eq . 2$$

$${I}_{COMP} = \frac{{V}_{H}}{{V}_{X}} \cdot \frac{{I}_{HN}}{\sqrt{3}} \qquad Eq . 3$$

$${Z}_{COMP} = {Z}_{1 T} \cdot ( 3 \cdot {k}_{0} + 1 ) - {Z}_{0 T} \qquad Eq . 4$$

where:
V_{A} is the compensated A-phase voltage;
V_{B} is the compensated B-phase voltage;
V_{C} is the compensated C-phase voltage;
V_{XA} is the measured delta-side A-phase voltage;
V_{XB} is the measured delta-side B-phase voltage;
V_{XC} is the measured delta-side C-phase voltage;
I_{A} is the compensated A-phase current;
I_{B} is the compensated B-phase current;
I_{C} is the compensated C-phase current;
I_{XA} is the measured delta-side A-phase current;
I_{XB} is the measured delta-side B-phase current;
I_{XC} is the measured delta-side C-phase current;
V_{H} is the nominal wye-side line-to-line voltage;
V_{X} is the nominal delta-side line-to-line voltage;
k₀ is the ground distance protection zero-sequence compensating factor selected based on the line impedances;
Z_{1T} is the positive-sequence impedance of the GSU transformer on the delta-side base; and,
Z_{0T} is the zero-sequence impedance of the GSU transformer on the delta-side base.

Although Equations 1-4 are written for phasors, the voltage and current phasors can be directly replaced by voltage and current samples by using the concept of a replica impedance applied to the Z_{COMP} current multiplier. The solution is therefore general, allowing any of the standard ground and phase distance protection elements to be employed, including those based on instantaneous samples.

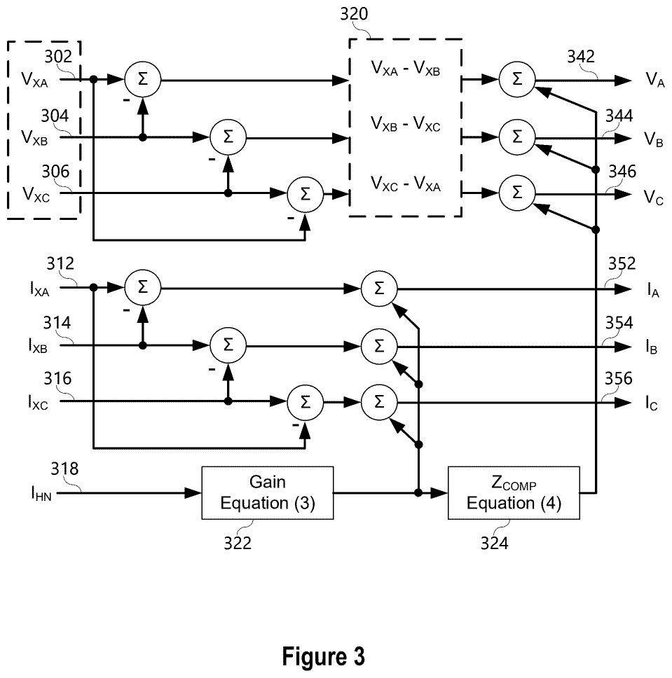

FIG. 3 illustrates a flow diagram that may be used to calculate compensated voltages and currents for each phase using the delta-side voltages and currents and the wye-side neutral currents. A compensating current factor is calculated using the neutral-point current 318 and a gain calculator 322 that uses nominal delta- and wye-side line-to-line voltages and (see also Equation 3). Similarly, a compensating impedance factor is calculated in calculator 324 using positive- and zero-sequence impedances of the transformer on the delta-side. Differences between each pair of the delta-side A-, B-, and C-phase voltages 302, 304, and 306 are calculated 320, and summed with the products of the compensating current factor 322 and compensating impedance factor 324 to produce compensated A-, B-, and C-phase voltages 342, 344, 346. Alternatively, when delta-connected PTs are used, the IED 110 measures the voltage differences 320 directly and there is no need to subtract the phase to ground voltages. Similarly, differences between each pair of delta-side A-, B-, and C-phase currents 312, 314, 316 are calculated and summed with the compensating current factor 322 to produce compensated A-, B-, and C-phase currents 352, 354, 356. These compensated voltages and currents may be used for both phase and ground distance protection on the wye-side of the transformer. In several embodiments herein, this distance protection is used as a backup distance protection

The compensated voltages and currents from Equations 1-2 may be used to excite ground distance element logic to provide the backup protection for ground system faults, and phase distance element logic to provide the backup protection for phase system faults. Equation 2 calculates compensated currents that can be used in a distance element. In accordance with certain embodiments, these compensated currents may be used for faulted-loop selection, overcurrent supervision, and other internal applications in a distance element logic. Currents used for ground and phase distance protection may be calculated using the currents from Equation 2, and include a zero-sequence compensation factor, k₀. In accordance with certain embodiments, the zero-sequence compensation factor may be selected based on impedances.

Equation 5 illustrates the calculation of ground loop current (I_{AG}, I_{BG}, and I_{CG}) that are calculated using the compensated currents, and which may be used in a ground distance element:

$$\begin{matrix}{I}_{AG} + {I}_{A} + {k}_{0} \cdot 3 {I}_{0} = {I}_{XA} - {I}_{XB} + {I}_{COMP} \cdot ( 3 {k}_{0} + 1 ) \\ {I}_{BG} + {I}_{B} + {k}_{0} \cdot 3 {I}_{0} = {I}_{XB} - {I}_{XC} + {I}_{COMP} \cdot ( 3 {k}_{0} + 1 ) \\ {I}_{CG} + {I}_{C} + {k}_{0} \cdot 3 {I}_{0} = {I}_{XC} - {I}_{XA} + {I}_{COMP} \cdot ( 3 {k}_{0} + 1 )\end{matrix} \qquad Eq . 5$$

Equation 1 calculates the distance element input voltages. These input voltages can be used for polarization (self-, cross-, or memory polarization). Memory polarization in generator applications may be detrimental due to possible large frequency excursions. Memory polarization is not strictly needed because the delta-side voltages during a transmission line fault are never zero due to the impedance of the GSU transformer, even for close-in, metallic, three-phase faults in the system.

The ground distance element in accordance with certain embodiments may be self-polarized, or it can use a concept of an offset impedance and evaluate backwards up to a fraction of the stator impedance.

Equations 1 and 2 may be used to replicate the wye-side voltages and currents and as such apply to both ground and phase distance elements. Loop quantities for all phase loops may be calculated from these voltages and currents. For example, AB loop quantities may be calculated using Equations 6 and 7:

$$\begin{matrix}{V}_{AB} = {V}_{A} - {V}_{B} \\ = ( {V}_{XA} - {V}_{XB} + {I}_{COMP} \cdot {Z}_{COMP} ) - ( {V}_{XB} - {V}_{XC} + {I}_{COMP} \cdot {Z}_{COMP} ) \\ = {V}_{A} - 2 \cdot {V}_{B} + {V}_{C}\end{matrix} \qquad Eq . 6$$

$$\begin{matrix}{V}_{BC} = {V}_{B} - {V}_{C} \\ = ( {V}_{XB} - {V}_{XC} + {I}_{COMP} \cdot {Z}_{COMP} ) - ( {V}_{XC} - {V}_{XA} + {I}_{COMP} \cdot {Z}_{COMP} ) \\ = {V}_{B} - 2 \cdot {V}_{C} + {V}_{A}\end{matrix}$$

$$\begin{matrix}{V}_{CA} = {V}_{C} - {V}_{A} \\ = ( {V}_{XC} - {V}_{XA} + {I}_{COMP} \cdot {Z}_{COMP} ) - ( {V}_{XA} - {V}_{XB} + {I}_{COMP} \cdot {Z}_{COMP} ) \\ = {V}_{C} - 2 \cdot {V}_{A} + {V}_{B}\end{matrix}$$

$$\begin{matrix}{I}_{AB} = {I}_{A} - {I}_{B} \\ = ( {I}_{XA} - {I}_{XB} + {I}_{COMP} ) - ( {I}_{XB} - {I}_{XC} + {I}_{COMP} ) \\ = {I}_{A} - 2 \cdot {I}_{B} + {I}_{C} \\ = - 3 \cdot {I}_{B}\end{matrix} \qquad Eq . 7$$

$$\begin{matrix}{I}_{BC} = {I}_{B} - {I}_{C} \\ = ( {I}_{XB} - {I}_{XC} + {I}_{COMP} ) - ( {I}_{XC} - {I}_{XA} + {I}_{COMP} ) \\ = {I}_{B} - 2 \cdot {I}_{C} + {I}_{A} \\ = - 3 \cdot {I}_{C}\end{matrix}$$

$$\begin{matrix}{I}_{CA} = {I}_{C} - {I}_{A} \\ = ( {I}_{XC} - {I}_{XA} + {I}_{COMP} ) - ( {I}_{XA} - {I}_{XB} + {I}_{COMP} ) \\ = {I}_{C} - 2 \cdot {I}_{A} + {I}_{B} \\ = - 3 \cdot {I}_{A}\end{matrix}$$

Accordingly, the phase-to-phase voltages and currents on the delta side of the GSU transformer along with the current in the neutral of the wye side of the GSU transformer may be used in accordance with embodiments herein to derive phase voltages and currents that accurately replicate the wye-side phase quantities calculated in Equations 1 and 2. The positive- and zero-sequence impedances of the GSU transformer may be used in the protection element. These impedances are typically readily available from databases such as a short-circuit program database or calculated sing event records.

Equations 1 and 2 may be expanded to various transformer types and connections. For example, the Equations 1 and 2 may be derived for a GSU transformer YNd1 connection. Equations for other delta-wye GSU transformers, such as YNd11, may be derived by rotating indices in Equations 1 and 2.

As stated above, the voltages and currents calculated using Equations 1-7 may be used in various distance protection elements. Distance protection elements used in electric power system protection include various comparators joined by an AND gate. For example, a quadrilateral distance element may include a reactance comparator, a right blinder comparator, a left blinder comparator, a directional comparator, and/or a phase selection comparator. A mho distance element may include, among others, a mho comparator, phase selection comparator, and the like. Comparators for distance protection may be expressed by two signals, namely, an operating signal Sop and a polarizing signal S_{POL}. A comparator asserts an output if the operating signal and polarizing signal are approximately in-phase, and a protective action may then be taken.

To provide backup distance protection through a transformer that introduces a break in the zero-sequence equivalent network using only the low (or delta) side voltages and currents and the high (or wye) side neutral current, an IED may use a distance protection element that relies on compensated voltages and currents as calculated above. A ground distance protection element may calculate phase ground currents using Equation 5, and use those phase ground currents to determine operating and polarizing signals. The operating and polarizing signals may be compared to determine a fault within a predetermined zone of protection. The ground distance element may use compensated voltages used for polarization (self-, cross-, or memory-polarization). The ground distance element may be self-polarized, or it can use a concept of an offset impedance and evaluate backwards up to a fraction of the stator impedance. The ground distance element may use, for example, mho or quadrilateral characteristics as described in further detail below.

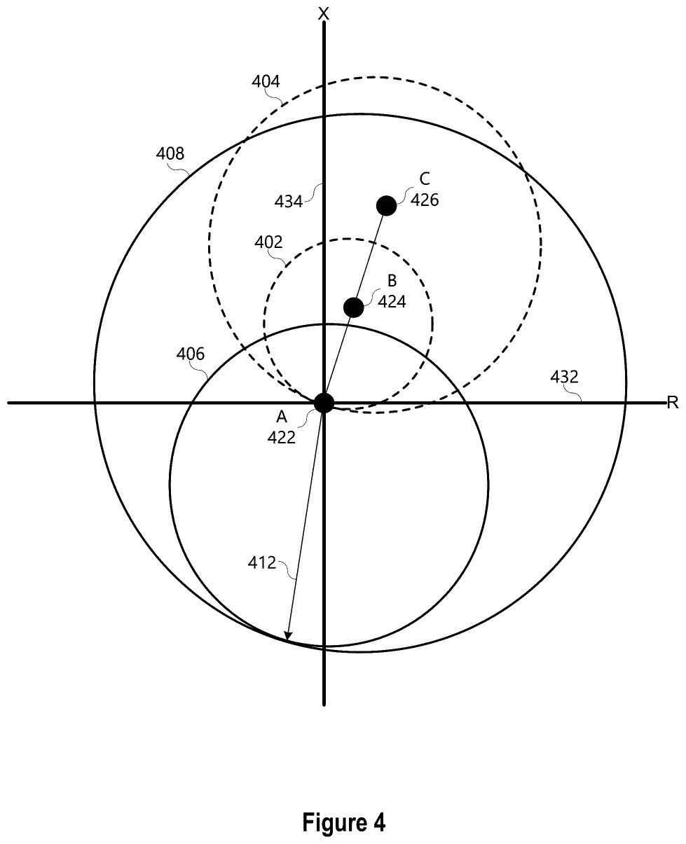

FIG. 4 illustrates primary and backup mho characteristics that may be used for four zones of protection. An impedance plane is illustrated with resistance on the horizontal axis 432 and reactance on the vertical axis 434. Line relay zone 1 402 and line relay zone 2 404 characteristics are illustrated, which may be used by an IED for providing ground distance protection to the transmission line. The origin represents the transformer high-side (wye-side) terminals. Accordingly, the generator zone 2 characteristic 406 and the generator zone 3 characteristic 408 for the backup distance protection originate at the low-voltage GSU terminal and are therefore shifted by the transformer positive-sequence impedance 412. When a fault impedance is calculated to be within the characteristic, the IED may issue a trip command (which may include a time delay).

The illustrated faults A 422, B 424, and C 426 are on the high (wye) side of the transformer. A fault at 0% reach is illustrated on the impedance plane at point A 422. As illustrated, this impedance is within all four of the characteristics. Thus, the line zone 1 protection would detect and trip for this fault, as would the backup protection (which may include a time delay). A fault at 40% reach in the forward direction is illustrated at point B 424. This fault is detected within line protection zone 1 402 and within generator zone 3 408. Similarly, a fault at 100% reach in the forward direction yields an impedance at C 426. This fault is detected within line protection zone 2 404 and generator zone 3. In various embodiments, time delays may be implemented among the various zones. For example, a 0.5 second time delay may be implemented for line zone 2 and for generator zone 2, and a 1 second time delay may be implemented for generator zone 3. Accordingly, the generator protection will delay a trip command for fault A 422 by 0.5 seconds so that line protection zone 1 may first issue a trip command. Similarly, generator protection would delay a trip command for 1 second for faults at B 424 and C 426, as each of these are outside of generator zone 2 but within generator zone 3.

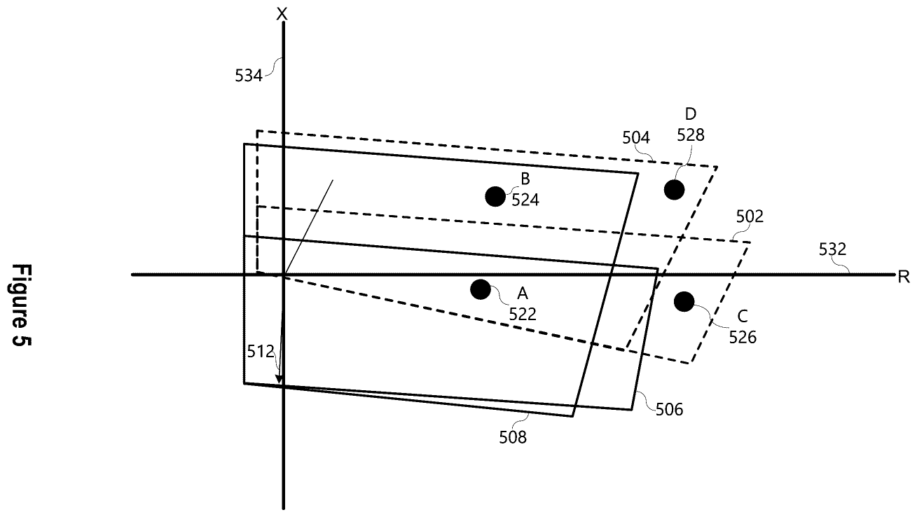

FIG. 5 illustrates a quadrilateral element for line and generator distance protection that may use the compensated voltages and currents in accordance with several embodiments herein. The element is illustrated on an impedance plane with a resistance axis 532 and a reactance axis 534. The origin represents the high (wye) side terminals of the transformer, with the line distance protection zone 1 characteristic 502 and zone 2 characteristic 504 passing through the origin. The generator backup distance protection zone 2 characteristic 506 and zone 3 characteristic 508 originate at the low-voltage GSU terminal and are therefore shifted by the transformer positive sequence impedance. Line and generator zone 2 may include a 0.5 second time delay, and generator zone 3 may include a 1 second time delay.

For a 30-ohm at 0% reach (point A 522), line protection zone 1 502 trips first and generator protection zone 2 506 provides a backup trip (in 0.5 seconds). Similarly, for a 25-ohm fault at 100% reach (point B 524), line protection zone 2 504 trips first and generator protection zone 3 508 provides a backup trip (in 1 second).

For a 60-ohm fault at 0% reach (point C 526), line protection zone 1 502 trips first and generator protection zone 2 506 does not. Similarly, for a 50-ohm fault at 100% reach (point D 528), line protection zone 2 504 trips first and generator protection zone 3 508 does not. These results verify resistive reach coordination to confirm that the backup zones are secure and dependable.

Thus, it can be seen that distance protection in accordance with embodiments herein may be applied to an electric power delivery system on a second side of a transformer that introduces a break in the equivalent zero-sequence network using the voltages and currents from a first side of the transformer, along with a neutral current from the second side. The neutral current and transformer nominal values may be used to calculate compensating factors, which are used to calculate compensated voltages and currents. The compensated voltages and currents may be used in distance protection elements to determine fault conditions on the second side of the transformer. The distance protection elements may be ground distance elements and/or phase distance elements. In various embodiments, the compensated voltages and currents may be used to provide backup distance protection. The backup distance protection may be performed by a generator protection relay, which receives the required voltages and currents for other protective functions. As a result of this disclosure, backup protection is provided by ground distance elements and not by overcurrent elements. Therefore, the backup ground fault protection can be coordinated better with the system ground fault protection.

While specific embodiments and applications of the disclosure have been illustrated and described, it is to be understood that the disclosure is not limited to the precise configurations and components disclosed herein. Moreover, principles described herein may also be used for primary distance protection, and other protective functions where a break in the zero-sequence network is introduced by electric power system equipment. Accordingly, many changes may be made to the details of the above-described embodiments without departing from the underlying principles of this disclosure. The scope of the present invention should, therefore be determined only by the following claims.

What is claimed:

1. A generator protection relay of an electric power delivery system, the generator protection relay comprising:
a signal processing subsystem to obtain power system signals and to produce:
stator current signals related to phase currents of a stator of a generator;
stator voltage signals related to phase voltages of the stator of the generator; and
transformer neutral current signals related to a current on a neutral of a second side of a transformer, wherein the transformer receives electric power from the generator;
a protection element to:
determine a compensating current factor using the transformer neutral current signals;
determine transformer second side compensated currents using the stator current signals and the compensating current factor;
determine transformer second side compensated voltages using the stator voltage signals, and the compensating current factor;
implement a distance element to detect a fault condition within a zone of protection using the determined transformer second side compensated voltages and the determined transformer second side compensated currents; and,
assert a protective action upon determination of the fault condition.

2. The system of claim 1, wherein the compensating current factor is determined using the transformer neutral current signals and nominal transformer values.

3. The system of claim 1, wherein the protection element is further configured to: calculate a compensating impedance factor.

4. The system of claim 3, wherein the protection element further determines the transformer second side compensated voltages using the compensating impedance factor.

5. The system of claim 1, wherein the protection element is further configured to:
determine a distance element operating signal from the transformer second side compensated currents and the transformer second side compensated voltages;
calculate a polarizing signal; and
compare the operating signal and the polarizing signal to determine the fault condition.

6. A method for fault coverage through a generator step-up (GSU) transformer of an electric power delivery system, comprising:
an intelligent electronic device (IED) in communication with the electric power delivery system obtaining
transformer first side current signals related to phase currents of a first side of the transformer;
transformer first side voltage signals related to phase voltages of the first side of the transformer; and
transformer neutral current signals related to a current of a neutral of a second side of the transformer;
determining a compensating current factor using the transformer neutral current signals;
determining transformer second side compensated currents using the transformer first side current signals and the compensating current factor;
determining transformer second side compensated voltages using the transformer first side voltage signals, and the compensating current factor;
exciting a distance element with the determined transformer second side compensated currents and the determined transformer second side compensated voltages to determine a fault condition within a zone of protection; and,
asserting a protective action upon determination of the fault condition.

7. The method of claim 6, further comprising determining the compensating current factor using the transformer neutral current signals and nominal transformer values.

8. The system of claim 6, further comprising calculating a compensating impedance factor.

9. The system of claim 8, further comprising determining the transformer second side compensated voltages using the compensating impedance factor.

10. A system for protecting an electric power delivery system that includes a transformer, comprising:
a signal processing subsystem to obtain power system signals and to produce:
transformer first side current signals related to phase currents of a first side of the transformer;
transformer first side voltage signals related to phase voltages of the first side of the transformer; and
transformer neutral current signals related to a current of a neutral of a second side of the transformer;
a protection element to:
determine a compensating current factor using the transformer neutral current signals;
determine transformer second side compensated currents using the transformer first side current signals and the compensating current factor;
determine transformer second side compensated voltages using the transformer first side voltage signals, and the compensating current factor;
implement a distance element to detect a fault condition within a zone of protection using the determined transformer second side compensated voltages and the determined transformer second side compensated currents; and,
assert a protective action upon determination of the fault condition.

11. The system of claim 10, wherein the protection element is further configured to: calculate a compensating impedance factor.

12. The system of claim 11, wherein the protection element further determines the transformer second side compensated voltages using the compensating impedance factor.

13. The system of claim 10, wherein the protection element is further configured to:
determine a distance element operating signal from the transformer second side compensated currents and the transformer second side compensated voltages;
calculate a polarizing signal; and
compare the operating signal and the polarizing signal to determine the fault condition.

14. The system of claim 10, wherein the distance element comprises a mho characteristic.

15. The system of claim 10, wherein the distance element comprise a quadrilateral characteristic.

16. The system of claim 10, wherein the protection element is further configured to calculate phase ground currents using the compensating current factor.

17. The system of claim 16, wherein the protection element is further configured to determine the distance element operating signal from the phase ground currents.

18. The system of claim 10, wherein the protection element is further configured to:
calculate phase loop currents using the transformer second side compensated currents and the compensating current factor; and
calculate phase loop voltages using the transformer second side compensated voltages.

19. The system of claim 18, wherein the protection element is further configured to determine the distance element operating signal from the phase loop currents and the phase loop voltages.

20. The system of claim 10, wherein the protection element further comprises a predetermined time delay coordinated with a primary distance protection element, and the protective action is only asserted after the time delay.
